(19) United States
(12) Patent Application Publication
(10) Pub. No.: US 2026/0188413 A1
(43) Pub. Date: Jul. 2, 2026

(54) COMBINATIONAL ERROR CONTROL COMPONENTS IN STACKED MEMORY SYSTEMS

(71) Applicant: Micron Technology, Inc., Boise, ID (US)

(72) Inventors: Marco SFORZIN, Cernusco Sul Naviglio (IT); Emanuele CONFALONIERI, Segrate (IT)

(21) Appl. No.: 19/371,379

(22) Filed: Oct. 28, 2025

Related U.S. Application Data
(60) Provisional application No. 63/739,334, filed on Dec. 27, 2024.

(51) Int. Cl. G11C 29/42

(52) U.S. Cl. CPC G11C 29/42

(57) ABSTRACT

In some implementations, a memory system may obtain, from a host system, a command to read data, where the memory system comprises a vertical stack of one or more memory dies. The memory system may retrieve, from a memory die of the one or more memory dies, a codeword associated with the data. The memory system may perform, using a combinational error control component, a double symbol error control operation on the codeword. The memory system may provide the data to the host system.

### CROSS-REFERENCE TO RELATED APPLICATION

This patent application claims priority to U.S. Provisional Patent Application No. 63/739,334, filed on Dec. 27, 2024, entitled “COMBINATIONAL ERROR CONTROL COMPONENTS IN STACKED MEMORY SYSTEMS,” and assigned to the assignee hereof. The disclosure of the prior application is considered part of and is incorporated by reference into this patent application.

### TECHNICAL FIELD

The present disclosure generally relates to memory devices, memory device operations, and, for example, to combinational error control components in stacked memory systems.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system that supports combinational error control components in stacked memory systems.

FIGS. 2A, 2B, and 2C depict various views of a system that supports combinational error control components in stacked memory systems.

FIG. 3 is a diagram illustrating an example of an encoder that supports combinational error control components in stacked memory systems.

FIG. 4 is a diagram illustrating an example of a system that supports combinational error control components in stacked memory systems.

FIG. 5 is a diagram illustrating an example of a system that supports combinational error control components in stacked memory systems.

FIG. 6 is a diagram illustrating an example of a system that supports combinational error control components in stacked memory systems.

FIG. 7 is a diagram illustrating an example of a system that supports combinational error control components in stacked memory systems.

FIG. 8 is a flowchart of an example method associated with combinational error control components in stacked memory systems.

### DETAILED DESCRIPTION

Some memory systems, such as high bandwidth memory (HBM) devices, may include a vertical stack of one or more memory dies. In some cases, the memory die(s) may be stacked on an interface, such as a buffer die, which may facilitate communication between the memory dies and a host system. In some cases, such memory systems may process data (e.g., may store data to a memory array or may retrieve data from a memory array) as one or more data frames, where a single data frame may be stored to a single bank of a single memory die of the stack. Such memory systems may implement error control schemes capable of correcting up to two errors in a data frame.

In some cases, to implement such an error correction scheme, a memory system may partition a data frame into two codewords to facilitate error correction using a single symbol correction (SSC) scheme. By dividing the data frame, the memory system may use an SSC scheme to correct a single error in each codeword independently, thus allowing for correction of up to two errors in the data frame. However, this approach may be limited in its ability to correct multiple errors that span across the entire data frame, such as two errors that occur in a single codeword.

Some implementations described herein enable combinational error control components in stacked memory systems. For example, a memory system that includes a vertical stack of memory dies, such as an HBM device, may implement one or more combinational error control components configured to perform double symbol error control operations, such as double symbol correction (DSC) operations, to encode and decode a data frame that includes a single codeword (e.g., a data frame that is not partitioned into multiple codewords).

A combinational error control component may include one or more combinational circuits. As described herein, a combinational circuit is a circuit having an output that, for a given time, is dependent on one or more inputs at the given time, regardless of previous inputs to the circuit (e.g., regardless of inputs prior to the given time). For example, a combinational circuit may include one or more adder circuits configured to obtain a set of inputs and output the sum of the inputs, one or more subtractor circuits configured to obtain a set of inputs and output a difference of the inputs, one or more exclusive- or (XOR) circuits to obtain a set of inputs and output the result of a XOR operation of the inputs, one or more multiplexers, and/or one or more demultiplexers, among other examples. Because the output of a combinational circuit depends on current inputs, rather than a combination of current and previous inputs, the performance of combinational circuits may be greater than other types of circuits, such as sequential circuits in which an output depends on both the current inputs and previous inputs. For example, a sequence of combinational circuits may obtain one or more inputs and generate one or more outputs in a reduced quantity of clock cycles (e.g., a single clock cycle), as compared with a sequence of sequential circuits.

In some examples, the one or more combinational control circuits may be implemented in the memory die(s) of the memory system. For example, a memory die may include a combinational error control component for each channel and/or pseudo-channel associated with the memory die. Alternatively, the one or more combinational error control components may be implemented in a buffer die of the memory system. For example, the buffer die may include a combinational error control component for each channel of the memory system.

As a result, by enabling combinational error control components in stacked memory systems, a vertically-stacked memory system may enable encoding and/or decoding a data packet using a DSC error correction scheme. For example, by encoding a data packet using a combinational error control component, the memory system may enable generating parity information for the DSC error scheme while reducing reliance on sequential circuits. Additionally, by generating the decoding values using the combinational error control component, the memory system may enable decoding the data packet while reducing reliance on sequential circuits. Said another way, the one or more combinational circuits may enable a fully-algebraic implementation of the DSC error correction scheme. Such an implementation may improve the performance of encoding and/or decoding a data packet, such as by reducing the quantity of resources (e.g., processing resources and/or energy resources) used to encode and/or decode the data packet, may increase the speed at which the data packet is encoded and/or decoded, and may reduce the complexity of processing circuitry used to encode and/or decode the data packet.

Further, by including a combinational error control component for each channel and/or pseudo-channel of each memory die, the memory system may increase the efficiency of encoding and decoding operations, for example by allowing multiple encoding and/or decoding operations to be performed in parallel across multiple memory dies. Alternatively, by including a combinational error control component for each channel in the buffer die, the total quantity of combination error control components may be reduced, which may reduce the amount of circuitry of the system 200 and thus reduce overall costs and manufacturing complexity, among other benefits.

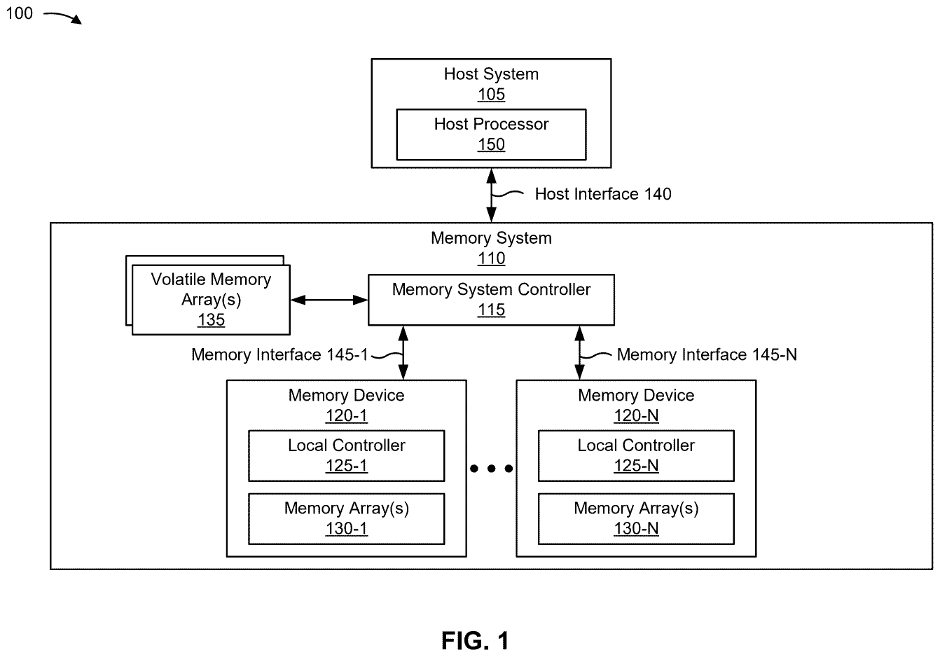

FIG. 1 is a diagram illustrating an example system 100 that supports combinational error control components in stacked memory systems. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to: obtain, from a host system, a command to read data, where the memory system comprises a vertical stack of one or more memory dies; retrieve, from a memory die of the one or more memory dies, a codeword associated with the data; perform, using a combinational error control component, a double symbol error control operation on the codeword; and provide the data to the host system.

In some implementations, one or more systems, devices, apparatuses, components, and/or controllers of FIG. 1 may include: a vertical stack of one or more memory dies; one or more channels configured to couple respective subsets of the one or more memory dies to a buffer die; and one or more combinational error control components, where a combinational error control component of the one or more combinational error control components is configured to perform a double symbol error control operation on a codeword associated with a memory die of the one or more memory dies.

In some implementations, one or more systems, devices, apparatuses, components, and/or controllers of FIG. 1 may include: a vertical stack of one or more memory dies; a buffer die comprising one or more combinational error control components, where a combinational error control component of the one or more combinational error control components is configured to perform a double symbol error control operation on a codeword associated with a memory die of the one or more memory dies; and one or more channels coupling respective subsets of the one or more memory dies to the buffer die.

In some implementations, one or more systems, devices, apparatuses, components, and/or controllers of FIG. 1 may be include a vertical stack of one or more memory dies, the one or more memory dies comprising respective sets of combinational error control components, where a combinational error control component of the respective sets of combinational error control components is configured to perform a double symbol error control operation on a codeword associated with a memory die of the one or more memory dies; and one or more channels configured to couple respective subsets of the one or more memory dies to a buffer die.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

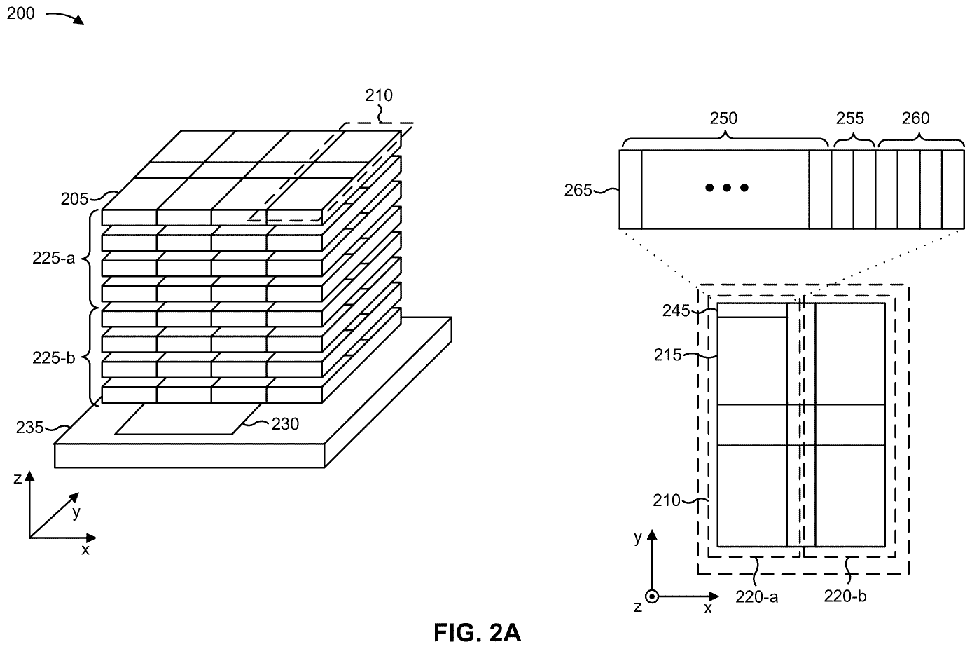

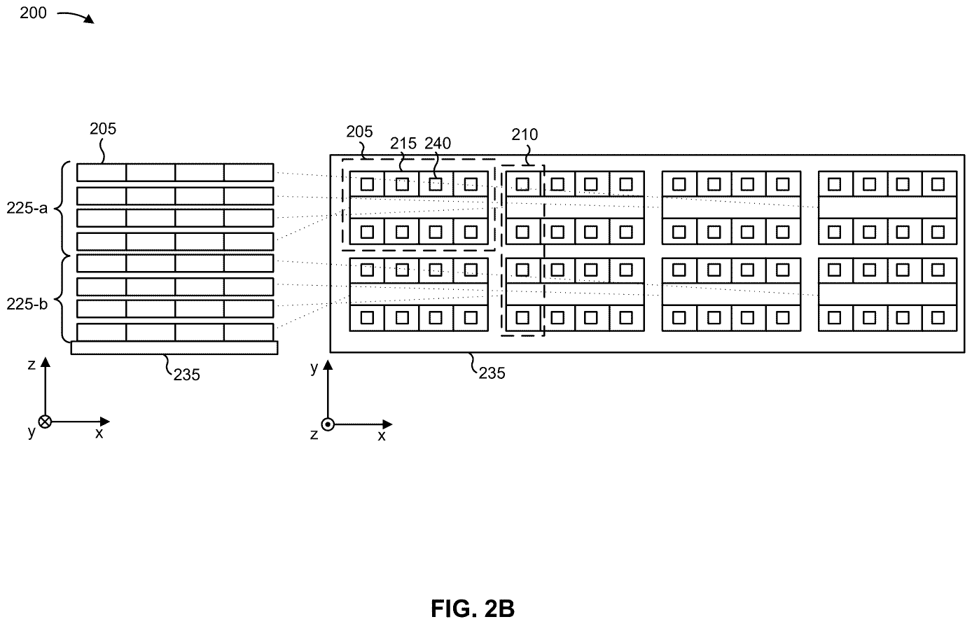

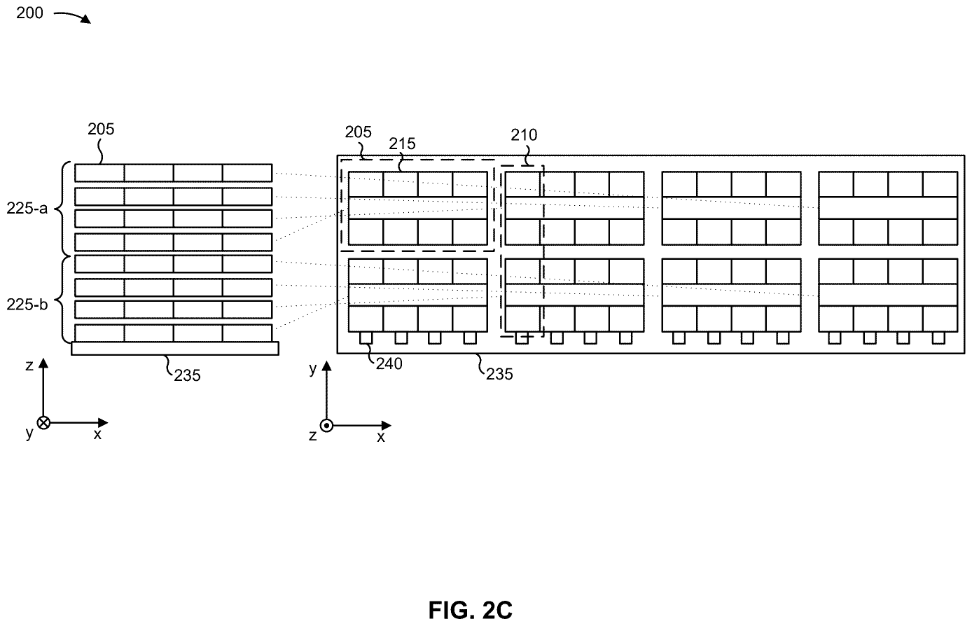

FIGS. 2A, 2B, and 2C depict various views of a system 200 that supports combinational error control components in stacked memory systems. For example, the system 200 may include a vertical stack of one or more memory dies 205 (e.g., one or more memory dies 205 stacked along the z-direction).

The system 200 may be organized according to one or more channels 210. A channel 210 may include an independent data pathway within the system 200 to support the transfer of data between the system 200 and a host system. A channel 210 may be associated with (e.g., may include, may be communicatively coupled with) a subset of one or more memory arrays 215 of a memory die 205. For example, as illustrated in FIGS. 2A-2C, a memory die 205 may be organized into one or more (e.g., four) channels 210, and each channel 210 may be associated with respective subsets of the one or more memory arrays 215 of the memory die 205. In some examples, a channel 210 may include one or more pseudo-channels 220, such as a pseudo-channel 220-a and a pseudo-channel 220-b. The one or more channels 210 and/or pseudo-channels 220 may operate concurrently, which may provide parallel data access to memory arrays 215 of different channels 210 and/or pseudo-channels 220, and thus enhance the overall bandwidth and performance of the system 200.

In some examples, the system 200 may include multiple stacked integrated dies (SIDs) 225, such as an SID 225-a and an SID 225-b. An SID 225 is a logical and/or physical partition of memory dies 205 within the system 200. In such examples, a channel 2120 may include memory arrays 215 from corresponding portions of different SIDs 225. For example, a channel 210 may include a subset of memory arrays 215 of a first memory die 205 of the SID 225-a. The channel 210 may further include a subset of memory arrays 215 of a second memory die 205 of the SID 225-b.

A channel 210 may facilitate communication between a memory array 215 and a controller. For example, a channel 210 may communicatively couple one or more memory arrays 215 to an interface 235 (e.g., a physical interface) of a buffer die 230. The buffer die 230 may include buffer circuitry and/or test logic components designed to facilitate data management and system diagnostics. For example, the buffer die 230 may manage data traffic between the vertically stacked memory dies 205 and a host system. Alternatively, a channel 210 may communicatively couple one or more memory arrays 215 directly to a host processor.

As shown in FIGS. 2B and 2C, the system 200 may include one or more combinational error control components 240. A combinational error control component 240 may implement a data protection scheme to increase the reliability of data stored to the one or more memory arrays 215. In some examples, as shown in FIG. 2B, a memory die 205 (e.g., each memory die 205) may include one or more combinational error control components 240. For example, a memory die 205 may include a combinational error control component 240 for each channel 210 and/or pseudo-channel 220 associated with the memory die 205. By way of illustrative example, for the system 200 depicted in FIG. 2B, each memory die 205 may include 8 combinational error control components 240, for a total of 64 combinational error control components 240 in the system 200. Alternatively, as shown in FIG. 2C, the one or more combinational error control components 240 may be implemented in the buffer die 230. For example, the buffer die 230 may include a combinational error control component 240 for each channel 210 of the system 200. By way of illustrative example, for the system 200 depicted in FIG. 2C, the buffer die 230 may include 16 combinational error control components 240.

By including a combinational error control component for each channel 210 and/or pseudo-channel 220 of each memory die 205, the system 200 may increase the efficiency of encoding and decoding operations, for example by allowing multiple encoding and/or decoding operations to be performed in parallel across multiple memory dies 205. Alternatively, by including a combinational error control component 240 for each channel 210 in the buffer die 230, the total quantity of combination error control components 240 may be reduced, which may reduce the amount of circuitry of the system 200 and thus reduce overall costs and manufacturing complexity, among other benefits.

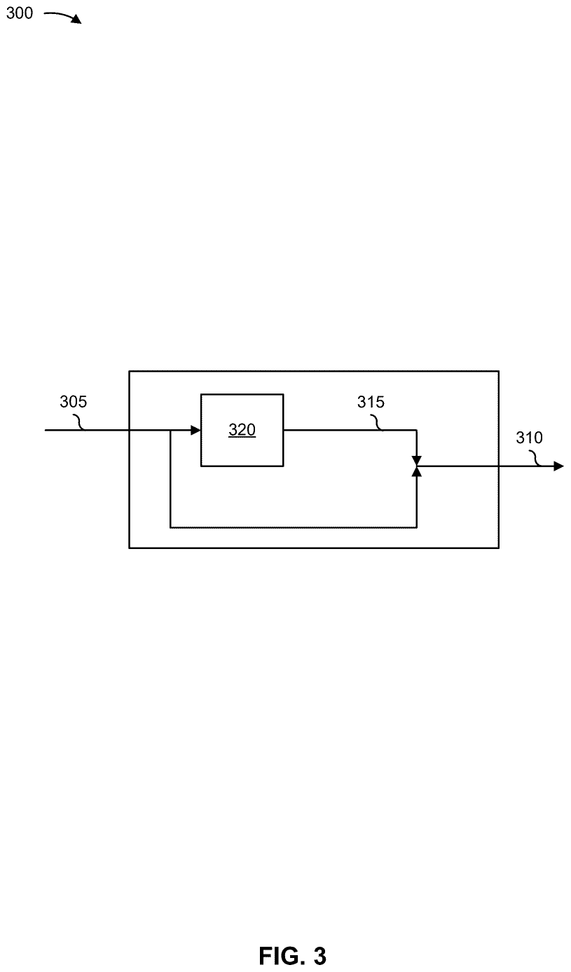

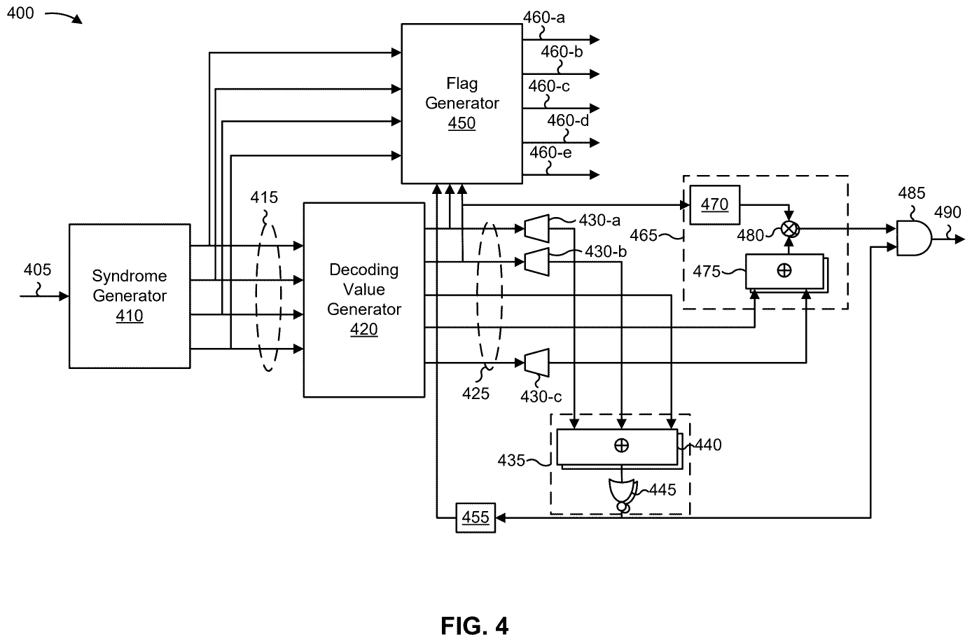

A combinational error control component 240 may include an encoder configured to generate a codeword 245, as described in greater detail in connection with FIG. 3. The system 200 may store the codeword 245 to a bank of a memory array 215 as part of a write command. Additionally, a combinational error control component 240 may include a decoder configured to decode a codeword 245, as described in greater detail in connection with FIG. 4. The system 200 may retrieve the codeword 245 from the memory array 215 as part of a read command. A codeword 245 may include a payload 250 (e.g., user data). A codeword 245 may further include system metadata 255. The system metadata 255 may include metadata managed and/or generated by the host system, such as end-to-end parity information or other metadata. A codeword 245 may further include parity information 260, which may be generated by the encoder.

A codeword 245 may be organized into one or more symbols 265. For example, the codeword 245 may include respective particular quantities of symbols 265 of payload 250, system metadata 255, and parity information 260. As described herein a symbol 265 refers to an 8-bit sequence of data (e.g., a byte). However, techniques described herein may apply to symbols of other sizes. For example, the codeword 245 may include 32 symbols 265 of payload 250, 2 symbols of system metadata 255, and 4 symbols of parity information 260, for a total of 38 symbols 265. Accordingly, the codeword 245 may include 38 total symbols 265, and thus 304 total bits. In some cases, the system 200 may operate according to a larger symbol size, such as a 16-bit symbol. In such cases, the system 400 may partition a larger symbol into one or more smaller symbols (e.g., may split a 16-bit symbol into 2 8-bit symbols) to generate and/or decode a codeword 245 using a combinational error control component 240.

In some examples, the memory system may obtain, from the host system, a command to store a payload 250 and/or system metadata 255 to the one or more memory arrays 215 (e.g., a write command). To store the payload 250 and/or the system metadata 255, the memory system may generate a codeword 245 using an encoder. The encoder may be configured to calculate parity information 260 using the payload 250 and/or the system metadata 255 by implementing one or more combinational circuits, as described in greater detail in connection with FIG. 3. The encoder may combine the parity information 260 with the payload 250 and/or the system metadata 255 to generate the codeword 245, such as by appending the parity information 260 to the payload 250 and/or the system metadata 255.

The parity information 260 may be configured to correct up to two corrupted symbols in the codeword 245. As described herein, a corrupted symbol is a symbol in which one or more bits of the symbol have changed value (e.g., changed value while being stored to the one or more memory arrays 215 and/or while being read from the one or more memory arrays 215). “A corrupted symbol” in data and “an error” in data may be used interchangeably. For example, the encoder may generate the parity information 260 using a DSC scheme, as described in greater detail in connection with FIG. 3. The parity information 260 may include a given quantity of data, such as 32 bits (e.g., four symbols). Symbols 265 of the codeword 245 may be ordered. For example, each symbol 265 of the codeword 245 may have a respective position, such as a symbol index. Said another way, the codeword 245 may be represented as a vector y of symbols yᵢ, where i∈{0, 1, 2 . . . 37}. In such a representation, the symbol yᵢ is the i^{th} symbol of the codeword 220 (e.g., the symbol yᵢ is in the i^{th} position of the codeword 220).

In some examples, the system 200 may obtain, from the host system, a command to read the payload 250 and/or the system metadata 255 from the one or more memory arrays 215 (e.g., a read command). To read the payload 250 and/or the system metadata 255, the system 200 may retrieve the codeword 245 from the one or more memory arrays 215. The system 200 may decode the codeword 245 to correct and/or detect one or more errors in the codeword 245 using one or more decoders. As described in greater detail in connection with FIG. 4, to decode the codeword 245, the system 200 may calculate a syndrome (e.g., one or more values that indicate information associated with the one or more errors in the codeword 245). Using the syndrome, the system 200 may attempt to detect one or more errors in the codeword 245. If the system 200 detects no errors in the codeword 245, the system 200 may issue the codeword 245 to the next stage of a read data path. Alternatively, if the system 200 detects one or more correctable errors in the codeword 245, then the system 200 may correct the one or more correctable errors using one or more combinational circuits. Subsequently, the system 200 may issue the (corrected) codeword 245 to the next stage of the read data path. The system 200 may thus provide the corrected payload 250 and/or system metadata 255 to the host system. In some examples, such as if the system 200 detected one or more uncorrectable errors, the system 200 may provide a message to the host system indicating that the payload 250 and/or system metadata 255 includes the one or more uncorrectable errors.

By encoding a codeword 245 using the combinational error control component 240, the system 200 may enable generating parity information for the DSC error scheme using one or more combinational circuits. Such an implementation may improve the performance of encoding the codeword 245, such as by reducing the quantity of resources (e.g., processing resources and/or energy resources) used to encode the codeword 245, by increasing the speed at which the combinational error control component 240 encodes the codeword 245, and/or reducing the complexity of processing circuitry used to encode the codeword 245.

Further, by decoding a codeword 245 using the combinational error control component 240, the system 200 may enable the DSC error scheme using one or more combinational circuits. Such an implementation may improve the performance of decoding the codeword 245, such as by reducing the quantity of resources (e.g., processing resources and/or energy resources) used to decode the codeword 245, by increasing the speed at which the combinational error control component 240 decodes the codeword 245, and/or reducing the complexity of processing circuitry used to decode the codeword 245.

As indicated above, FIGS. 2A-2C are provided as examples. Other examples may differ from what is described with regard to FIGS. 2A-2C.

FIG. 3 is a diagram illustrating an example of an encoder 300 that supports combinational error control components in stacked memory systems. The encoder 300 may be implemented in a combinational error control component, such as the combinational error control component 240. The encoder 300 may be configured to encode a payload 305, such as a payload 250 and/or system metadata 255, into a codeword 310 having parity information 315 capable of correcting up to two errors in the codeword 310.

The encoder 300 may encode the payload 305 using one or more combinational circuits in accordance with a DSC error correction scheme, such as a Reed-Solomon scheme (e.g., the parity information 315 may be a Reed-Solomon code). In accordance with the DSC error correction scheme, symbols of the payload 305 and/or the parity information 315 may be represented as elements of an algebraic field, such as a finite field (e.g., a Galois field). As described herein, an algebraic field is a set of elements on which operations including addition, subtraction, multiplication, and division are defined and satisfy one or more field rules. A finite field, which may also be called a Galois field, is a field having a finite quantity of elements. Finite fields may be defined, in part, by the quantity of elements included in the field. For example, a finite field having two elements may be referred to as the GF(2) field, a finite field having four elements may be referred to as the GF(4) field and/or the GF(2²) field, and so on. Thus, because symbols of the payload 305 and/or the parity information 315 may include eight bits, each possible symbol may be represented as a respective element of the GF(2⁸) field.

The encoder 300 may operate on such symbols according to the arithmetic (e.g., the one or more field rules) of the GF(2⁸) field. For example, the encoder 300 may perform operations between element of the GF(2⁸) field, such as addition, subtraction, multiplication, and/or division, such that the result of an operation is an element of the GF(2⁸) field (e.g., using modulo (mod) arithmetic). Each non-zero element of a finite field may be written in terms of a primitive element α. For example, each non-zero element of a finite field may be written as a′, where i is a natural number. Additionally, or alternatively, elements of a finite field may be represented as polynomials, and each element of the field may be written as a generator polynomial raised to a power. For example, the GF(2⁸) field may have a generator polynomial p(x)=x⁸+x⁴+x³+x₂=1.

To generate the parity information 315, the encoder 300 may use a DSC code having a generator polynomial g(x)=x⁴+α⁷⁶x³+α²⁵¹x²+α⁸¹x+α¹⁰. The encoder 300 may, using the one or more combinational circuits, multiply the payload 305 by a parity matrix 320. The parity matrix 320 may be defined as P^{T}, as shown in equation 1 below, where rᵢ (x)=x^{N-K+i} mod g (x), N is the quantity of symbols in the codeword 310 (e.g., 38 symbols), and K is the quantity of symbols in the payload 250 and/or the system metadata 255 (e.g., 32 symbols). In equation 1, each element rᵢ (x) is an element of the algebraic field represented as a polynomial (e.g., a polynomial function taking x as an independent variable).

$${P}^{T} = [ \begin{matrix}- {r}_{0} x \\ - {r}_{1} ( x ) \\ … \\ - {r}_{K - 1} ( x )\end{matrix} ] \qquad ( 1 )$$

For example, if the payload 305 and the parity information 315 are denoted as vectors d and p of symbols, respectively, then the parity information 315 may be obtained as shown in equation 2.

$$p = d {P}^{T} \qquad ( 2 )$$

To enable multiplication of the payload 305 by the parity matrix 320, the parity matrix 320 may be encoded as a matrix of symbols (e.g., may be encoded in a binary representation). After generating the parity information 315, the encoder 300 may combine the payload 305 and the parity information 315 (e.g., by appending the parity information 315 to the payload 305) to generate the codeword 310.

By encoding a payload 305 using the parity matrix 320, the encoder 300 may enable generating parity information for the DSC error scheme using a combinational error control circuit (e.g., the combinational error control circuit 240). Such an implementation may improve the performance of encoding the payload 305, such as by reducing the quantity of resources (e.g., processing resources and/or energy resources) used to encode the payload 305, by increasing the speed at which the encoder 300 encodes the payload 305, and/or by reducing the complexity of processing circuitry used to encode the payload 305.

As indicated above, FIG. 3 is provided as an example. Other examples may differ from what is described with regard to FIG. 3.

FIG. 4 is a diagram illustrating an example of a system 400 that supports combinational error control components in stacked memory systems. The system 400 may include aspects of and/or may be implemented by a memory apparatus, such as the memory system 110, a memory device 120, and/or the system 200. For example, the system 400 may be implemented in a combinational error control component, such as the combinational error control component 240. The system 400 may include one or more components configured to decode a codeword 405. The codeword 405 may be an example of the codeword 245 as described with reference to FIG. 2.

The system 400 may be configured to determine and/or correct multiple errors in the codeword 405. For example, the codeword 405 may be represented as a set (e.g., a vector), denoted as y, of symbols where a symbol at the i^{th} position in the codeword 405 may be denoted as yᵢ. The system 400 may generate an error vector 490, denoted as e, that is a vector of symbols (e.g., symbols representing an error in the codeword 405), where the i^{th} position in the error vector may be denoted as eᵢ. If the system 400 determines that a symbol yᵢ includes an error, then the element eᵢ may be equal to an error value associated with the error. Alternatively, if the system 400 does not detect an error in the symbol yᵢ, then the element eᵢ may be equal to zero (e.g., the zero element of the algebraic field). The system 400 may generate a corrected codeword, denoted as d, by combining the codeword 405 and the error vector 490. For example, the corrected codeword may be calculated by d=y+e. As described herein, an error value eᵢ is a symbol that, when added to the symbol yᵢ, produces a corrected symbol dᵢ, as described in greater detail elsewhere herein.

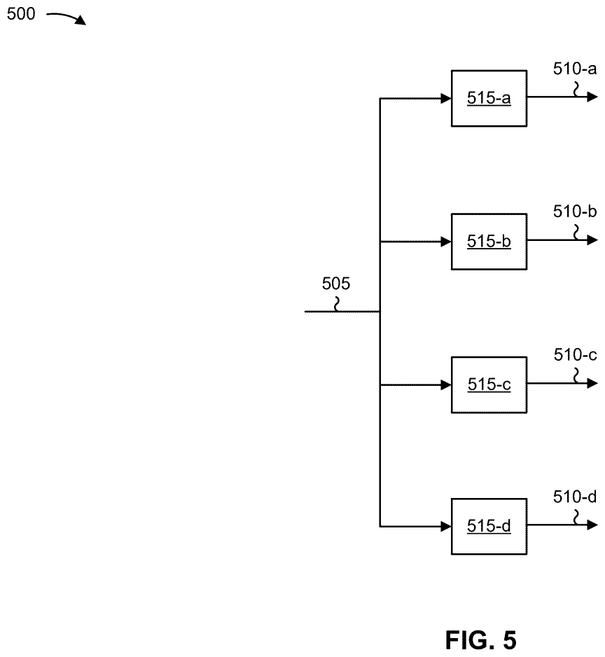

The system 400 may include a syndrome generator 410 configured to calculate a syndrome 415 for the codeword 405. The syndrome 415 may include one or more syndrome values S₁, S₂, S₃, and S₄ that may be elements of the algebraic field, as described in greater detail in connection with FIG. 5. The syndrome generator 410 may provide the syndrome 415 to a decoding value generator 430. For example, the syndrome generator 410 may output respective subsets of the one or more syndrome values to one or more combinational circuits of the decoding value generator 430.

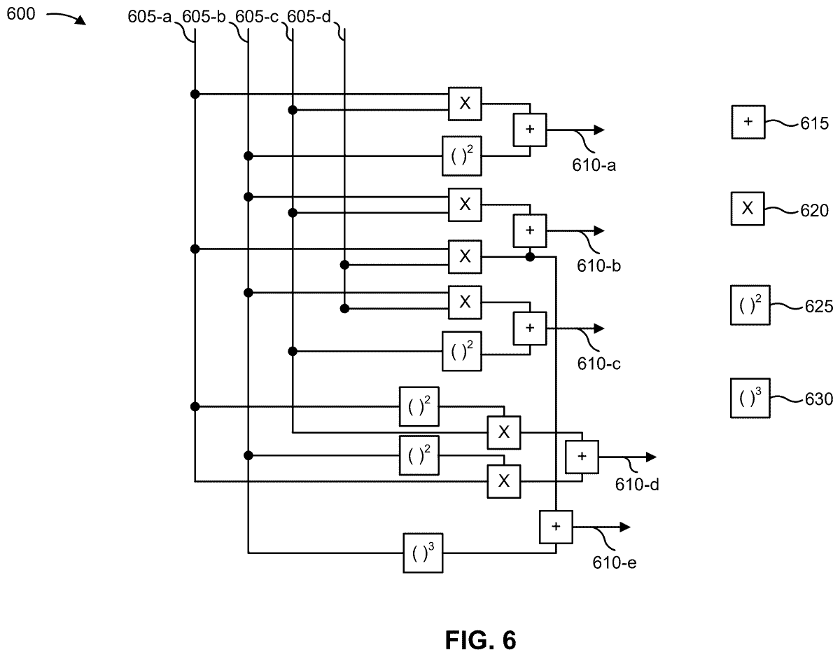

The decoding value generator 420 may be configured to, using one or more combinational circuits taking the syndrome 415 as a set of inputs, generate one or more decoding values 425 denoted as A, B, C, D, and E, as described in greater detail in connection with FIG. 6. Because the one or more decoding values 425 may be calculated using operations between the one or more syndrome values (e.g., additions and/or multiplications of the one or more syndrome values), each decoding value 425 may be an element of the algebraic field (e.g., each decoding value 425 may be an 8-bit symbol).

The one or more decoding values 425 may indicate information associated with the error vector e. The system 400 may use a first subset of the decoding values 425 to determine one or more positions i of non-zero error values eᵢ in the error vector e, and may use a second subset of the decoding values 425 to determine the error values eᵢ.

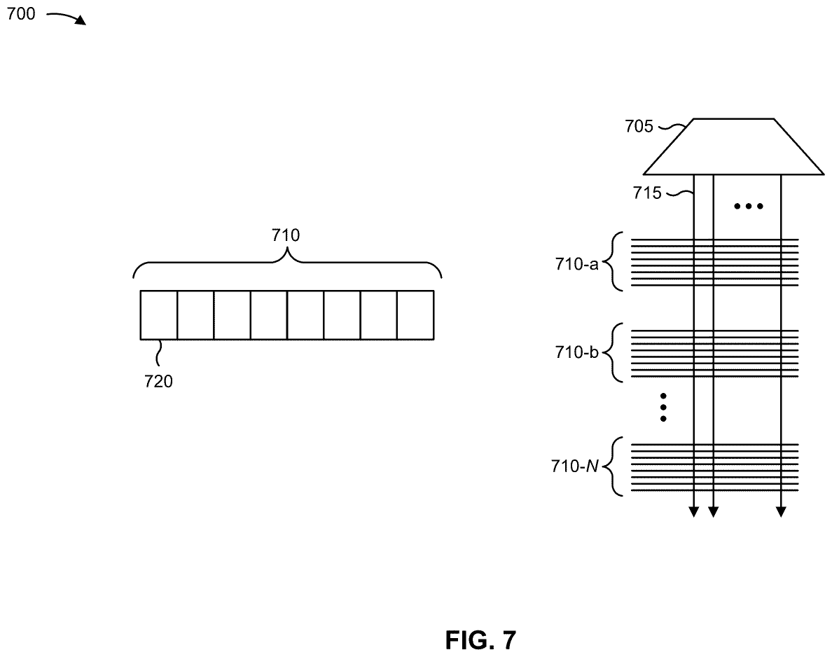

The decoding value generator 420 may provide one or more of the decoding values 425 to one or more coefficient generators 430. For example, the decoding value generator 420 may output respective decoding values 425 of the one or more decoding values 425 to a coefficient generator 430. The coefficient generator 430 may be configured to obtain a decoding value 425 and output one or more coefficients of an error position equation using the decoding value 425. Each coefficient may correspond to a respective position (a respective symbol index) in the codeword 405. For example, as explained in greater detail in connecting to FIG. 7, for i∈{0, 1, 2, . . . 37}, the coefficient generator 430-a may obtain the decoding value A and may output one or more coefficients Aα²ⁱ. The coefficient generator 430-b may obtain the decoding value B and may output one or more coefficients Bαⁱ. The coefficient generator 430-c may obtain the decoding value E and may output one or more coefficients Eα⁻ⁱ.

The decoding value generator 420 and/or the coefficient generators 430 may provide the coefficients Aα²ⁱ and Bαⁱ, as well as the decoding value C, to an error position generator 435. The error position generator 435 may include one or more combinational circuits 440 configured to determine whether one or more symbols of the codeword 405 include an error. In some implementations, the error position generator 435 may include a quantity of combinational circuits 440 equal to the quantity of symbols of the codeword 405.

In such examples, a combinational circuit 440 (e.g., the i^{th} combinational circuit 440) may be configured to determine whether the symbol yᵢ of the codeword 405 includes an error. For example, the combinational circuit 440 may obtain, as inputs, the coefficients Aα²ⁱ and Bαⁱ, as well as the decoding value C. The combinational circuit 440 may determine whether the inputs satisfy an equation. For example, as described in greater detail in connection with FIG. 7, the combinational circuit 440 may determine whether the equation Aα²ⁱ+Bαⁱ+C=0 is satisfied (e.g., if the sum of the coefficients Aα²ⁱ, Bαⁱ, and the decoding value decoding value C is equal to zero). If the inputs satisfy the equation, then the combinational circuit 440 may detect that an error exists in the i^{th} position of the codeword 405. Alternatively, if the inputs do not satisfy the equation, then the combinational circuit 440 may not detect that an error exists in the i^{th} position of the codeword 405.

To determine whether the inputs satisfy the equation, the combinational circuit 440 may include an adding circuit configured to compute the sum of the inputs and provide the result to a logic gate 445, such as a not-or (NOR) gate. If the result is equal to zero, then the logic gate 445 may output a first value (e.g., a logic “1”). Otherwise, the logic gate 445 may output a second value (e.g., a logic “0”). Accordingly, the error position generator 435 may output one or more error position values (e.g., a respective error position value for each combinational circuit 440), where the i^{th} error position value indicates whether the i^{th} symbol of the codeword 405 contains an error.

The error position generator 435 may provide an indication of the quantity of errors in the codeword 405 to a flag generator 450. For example, the error position generator 435 may provide the one or more error position values to a weight circuit 455. The weight circuit 455 may determine the quantity of errors in the codeword 405 (e.g., by summing the one or more error position values), and may provide the quantity to the flag generator 450.

The flag generator 450 may be configured to extract information associated with one or more errors in the codeword 405 using the syndrome 415 (e.g., provided by the syndrome generator 410), the one or more decoding values 425 (e.g., provided by the decoding value generator 420), and/or the quantity of errors in the codeword 405 (e.g., provided by the weight circuit 455). For example, the flag generator 450 may generate one or more flags 460 indicating information associated with the one or more errors. For example, if the flag generator 450 determines that there are no errors in the codeword 405, then the flag generator 450 may set the value of a flag 460-a (e.g., set the value to a logic “1”) and may reset the values of flags 460-b through 460-e (e.g., may set the respective values of the flags 460-b through 460-e to a logic “0”). Alternatively, if the flag generator 450 determines that the codeword 405 includes a correctable error, then the flag generator 450 may set the value of a flag 460-d. Additionally, the flag generator 450 may indicate whether the codeword 405 includes one error or two errors by setting the flags 460-b or 460-c, respectively. If the flag generator 450 determines that the codeword 405 includes an uncorrectable error, then the flag generator 450 may set the value of the flag 460-e. The flag generator 450 may provide the flags 460 to a host system 105 and/or a controller, such as the local controller 125 and/or the memory system controller 115.

The decoding value generator 420 and/or the coefficient generators 430 may provide the coefficients Eα⁻ⁱ, along with the decoding values B and D, to an error value generator 465. In some examples, the error position generator 435 may provide the one or more error position values to the error value generator 465. The error value generator 465 may be configured to determine one or more error values, where an error value et satisfies the equation Beᵢ=D+Eα⁻ⁱ, as described in greater detail in connection with FIG. 6. For example, because the algebraic field is finite, the error value generator 465 may test all possible values of eᵢ for each position i indicated by the error position values to determine the one or more error values that satisfy the equation.

Additionally, or alternatively, the error value generator 465 may include a combinational circuit 470, one or more combinational circuits 475, and one or more combinational circuits 480 configured to determine the one or more error values. The combinational circuit 470, along with a given set of the combinational circuits 475 and 480 (e.g., the i^{th} combinational circuits 475 and 480) may be configured to determine the error value eᵢ using the equation Beᵢ=D+Eα⁻ⁱ. For example, the i^{th} combinational circuit 475 may compute the sum of D and Eαⁱ. Additionally, the combinational circuit 470 may obtain the decoding value B and may determine the inverse of the decoding value B (e.g., B⁻¹, the inverse element of B in the algebraic field). The combinational circuit 480 may compute the product B⁻¹ (D+Eα⁻ⁱ) to compute the error value eᵢ.

To determine B⁻¹, the combinational circuit 470 may calculate B⁻¹ using a set of combinational circuits, such as one or more squarer circuits and/or one or more multiplicative circuits, as described in greater detail in connection with FIG. 7. For example, an inverse element α⁻¹ of an element a in a Galois field GF(2^{m}) can be calculated using a⁻¹=a² a²^{²} a²^{³} . . . a²^{^{m-1}}. Accordingly, if B is an element of a Galois field GF(2⁸), then B⁻¹=B²B⁴B⁸ B¹⁶ B³² B⁶⁴ B¹²⁸, and B⁻¹ may be calculated using the one or more squarer circuits and/or the one or more multiplicative circuits.

Additionally, or alternatively, to determine B⁻¹, the combinational circuit 470 may use a mapping between one or more elements of the algebraic field and one or more inverse elements of the algebraic field. The mapping may include a table (e.g., a look-up table) which, for each element in the algebraic field, includes an association between the element and the inverse of the element. Thus, the combinational circuit 470 may look up the value B in the mapping to determine B⁻¹.

The combinational circuit 480 may provide the error value eᵢ to one or more logic gates 485 (e.g., one or more AND gates). The one or more logic gates 485 may be configured to combine the error values eᵢ generated by the error value generator 465 to generate the error vector 490, denoted by e. For example, the one or more logic gates 485 may obtain the one or more error position values from the error position generator 435. To generate the i^{th} symbol of the error vector 490, the one or more logic gates 485 may determine whether the i^{th} error position value indicates that the i^{th} symbol of the codeword 405 includes an error. If the one or more logic gates 485 determine that the i^{th} symbol of the codeword 405 includes an error, then the one or more logic gates 485 may output the error value eᵢ for the i^{th} symbol of the error vector 490. Alternatively, if the one or more logic gates 485 determine that the i^{th} symbol of the codeword 405 does not include an error, then the one or more logic gates 485 may output zero (e.g., the zero element of the algebraic field) for the i^{th} symbol of the error vector 490.

Accordingly, the system 400 may output the error vector 490. To correct the codeword 405, the memory system (e.g., using the system 400 or another component) may add the error vector 490 to the codeword 405. Said another way, the corrected codeword d may be calculated according to d=y+e.

In some examples, the system 400 may be organized into one or more stages. For example, the system 400 may include a first stage corresponding to the syndrome generator 410, a second stage corresponding to the decoding value generator 420, a third stage corresponding to the coefficient generators 430, a fourth stage corresponding to the error position generator 435, and/or a fifth stage corresponding to the error value generator 465, among other examples. In such examples, each stage may be associated with a respective buffer, such as a volatile memory array 135 that includes a register. The system may temporarily store the output of stage to the respective buffer (e.g., may cache the output to a buffer) to control timing of the system 400. For example, during a first duration, the system 400 may generate the syndrome 415 and may store the syndrome 415 to a first buffer of the first stage. During a second duration subsequent to the first duration, the system 400 may issue the syndrome 415 from the first buffer to the decoding value generator 420. The decoding value generator 420 may generate the decoding values 425 and may store the decoding values 425 to a second buffer of the second stage. During a third duration subsequent to the second duration, the system 400 may issue the decoding values 425 from the second buffer to the coefficient generators 430. The coefficient generators 430 may generate the coefficients and may store the coefficients to a third buffer of the third stage. During a fourth duration subsequent to the third duration, the system 400 may issue the decoding values 425 from the second buffer and/or may issue the coefficients from the third buffer to the error position generator 435. The error position generator 435 may generate the one or more error position values and may store the one or more error position values to a fourth buffer of the fourth stage. During a fifth duration subsequent to the fourth duration, the system 400 may issue the decoding values 425 from the second buffer, may issue the coefficients from the third buffer, and/or may issue the one or more error position values from the fourth buffer to the error value generator 465 The error value generator 465 may generate the one or more error values and may store the one or more error values to a fifth buffer of the fifth stage. By implementing one or more buffers between stages of the system 400, the system 400 may control the timing of generating the corrected codeword, which may allow the system 400 to reduce the rate of power consumption (e.g., by increasing the duration between consecutive stages), which may allow for improved peak-power management.

By decoding a codeword 405, the system 400 may enable the DSC error scheme using a combinational error control circuit, such as the combinational error control circuit 240. Such an implementation may improve the performance of decoding the codeword 405, such as by reducing the quantity of resources (e.g., processing resources and/or energy resources) used to decode the codeword 405, by increasing the speed at which the system 400 decodes the codeword 405, and/or by reducing the complexity of processing circuitry used to decode the codeword 405.

As indicated above, FIG. 4 is provided as an example. Other examples may differ from what is described with regard to FIG. 4.

FIG. 5 is a diagram illustrating an example of a system 500 that supports combinational error control components in stacked memory systems. The system 500 may be an example of a syndrome generator, such as the syndrome generator 410. For example, the system 500 may be implemented within a combinational error control component for a memory system, such as within the combinational error control component 240.

The system 500 may be configured to obtain a codeword 505, which may be a codeword 505 and may be denoted as y, and generate one or more syndrome values 510 of a syndrome. For example, the system 500 may be configured to generate a syndrome value 510-a, denoted by S₁, using a combinational circuit 515-a, may be configured to generate a syndrome value 510-b, denoted by S₂, using a combinational circuit 515-b, may be configured to generate a syndrome value 510-c, denoted by S₃, using a combinational circuit 515-c, and/or may be configured to generate a syndrome value 510-d, denoted by S₄, using a combinational circuit 515-d.

The system 500 may generate a syndrome value 510 by multiplying (e.g., in accordance with the algebraic field) the codeword 505 by a power of a primitive element of the algebraic field using a combinational circuit 515. For example, the combinational circuit 515-a may multiply the codeword 505 by α to obtain S₁, the combinational circuit 515-b may multiply the codeword 505 by α² to obtain S₂, the combinational circuit 515-c may multiply the codeword 505 by α³ to obtain S₃, and the combinational circuit 515-d may multiply the codeword 505 by α⁴ to obtain S₄, as shown in equations 3 through 5.

$${S}_{1} = y ( α ) = {\sum }_{i = 0}^{37} {y}_{i} {α}^{i} = y {A}_{1} \qquad ( 3 )$$

$${S}_{2} = y ( {α}^{2} ) = {\sum }_{i = 0}^{37} {y}_{i} {α}^{2 i} = y {A}_{2} \qquad ( 4 )$$

$${S}_{3} = y ( {α}^{3} ) = {\sum }_{i = 0}^{37} {y}_{i} {α}^{3 i} = y {A}_{3} \qquad ( 5 )$$

$${S}_{4} = y ( {α}^{4} ) = {\sum }_{i = 0}^{37} {y}_{i} {α}^{4 i} = y {A}_{4} \qquad ( 6 )$$

As shown in equations 3 through 6, each syndrome value 510 may be calculated by multiplying the codeword 505 by a respective vector A₁, A₂, A₃, or A₄ defined in table 1.

TABLE 1

| | | | |
|---|---|---|---|
| ${A}_{1} = [ \begin{matrix}1 \\ α \\ {α}^{2} \\ {α}^{3} \\ {α}^{4} \\ … \\ {α}^{37}\end{matrix} ]$ | ${A}_{2} = [ \begin{matrix}1 \\ {α}^{2} \\ {α}^{4} \\ {α}^{6} \\ {α}^{8} \\ … \\ {α}^{74}\end{matrix} ]$ | ${A}_{3} = [ \begin{matrix}1 \\ {α}^{3} \\ {α}^{6} \\ {α}^{9} \\ {α}^{12} \\ … \\ {α}^{111}\end{matrix} ]$ | ${A}_{4} [ \begin{matrix}1 \\ {α}^{4} \\ {α}^{8} \\ {α}^{12} \\ {α}^{16} \\ … \\ {α}^{148}\end{matrix} ]$ |

As indicated above, FIG. 5 is provided as an example. Other examples may differ from what is described with regard to FIG. 5.

FIG. 6 is a diagram illustrating an example of a system 600 that supports combinational error control components in stacked memory systems. The system 600 may be an example of a decoding value generator, such as the decoding value generator 420. For example, the system 600 may be implemented within a combinational error control component, such as the combinational error control component 240. The system 600 may be configured to obtain one or more syndrome values 605 (shown as 605-a, 605-b, 605-c, and 605-d), which may be the syndrome values 610-a, 610-b, 610-c, and 610-d and may be denoted as S₁, S₂, S₃, and S₄, respectively, and generate one or more decoding values 610, which may be the one or more decoding values 425.

To generate the decoding values 610, the system 600 may include one or more combinational circuits. For example, the system 600 may include one or more addition circuits 615 configured to obtain two inputs and output the sum of the inputs in accordance with the algebraic field. Additionally, the system 600 may include one or more multiplicator circuits 620 configured to obtain two inputs and output the product of the inputs in accordance with the algebraic field. Additionally, the system 600 may include one or more squarer circuits 625 configured to obtain an input and output the square of the input in accordance with the algebraic field. Additionally, the system 600 may include one or more cubator circuits 630 configured to obtain an input and output the cube of the input in accordance with the algebraic field.

Using the addition circuits 615, the multiplicator circuits 620, the squarer circuits 625, and the cubator circuits 630, the system 600 may generate a decoding value 610-a, denoted as A, a decoding value 610-b, denoted as B, a decoding value 610-c, denoted as C, a decoding value 610-d, denoted as D, and a decoding value 610-e, denoted as E, as shown in equations 7 through 11.

$$A = {S}_{1} {S}_{3} + {S}_{2}^{2} \qquad ( 7 )$$

$$B = {S}_{2} {S}_{3} + {S}_{1} {S}_{4} \qquad ( 8 )$$

$$C = {S}_{3}^{2} + {S}_{2} {S}_{4} \qquad ( 9 )$$

$$D = {S}_{1}^{2} {S}_{3} + {S}_{1} {S}_{2}^{2} \qquad ( 10 )$$

$$E = {S}_{2}^{3} + {S}_{1}^{2} {S}_{4} \qquad ( 11 )$$

The one or more combinational circuits may perform respective operations in accordance with the algebraic field. For example, an addition circuit 615 may compute the XOR of the inputs and output the result. The system 600 may perform multiplicative operations as a sum of symbols in terms of the primitive element α. For example, equation 12 may illustrate a notation that enables multiplying, using the addition circuit 615, a symbol a having a j^{th} component (e.g., a j^{th} bit) denoted by aⱼ by a symbol b having a j^{th} component denoted by bⱼ.

$$a b = ( {\sum }_{j = 0}^{7} {a}_{j} {α}^{j} ) b = {\sum }_{j = 0}^{7} {a}_{j} ( b {α}^{j} ) \qquad ( 12 )$$

Equation number 13 may illustrate a notation that enables squaring, using the multiplicator circuit 620, a symbol a.

$${a}^{2} = {( {\sum }_{j = 0}^{7} {a}_{j} {α}^{j} )}^{2} = {\sum }_{j = 0}^{7} {a}_{j} {α}^{2 j} = a [ \begin{matrix}1 \\ {α}^{2} \\ {α}^{4} \\ {α}^{6} \\ {α}^{8} \\ {α}^{10} \\ {α}^{12} \\ {α}^{14}\end{matrix} ] \qquad ( 13 )$$

Equation number 14 may illustrate a notation that enables cubing, using the squarer circuit 625, a symbol a.

$$\begin{matrix}{a}^{3} = {( {\sum }_{j = 0}^{7} {a}_{j} {α}^{j} )}^{3} \\ = {( {\sum }_{j = 0}^{7} {a}_{j} {α}^{j} )}^{2} {\sum }_{j = 0}^{7} {a}_{j} {α}^{j} \\ = {\sum }_{j = 0}^{7} {a}_{j} {α}^{2 j} {\sum }_{j = 0}^{7} {a}_{j} {α}^{j} \\ = {\sum }_{j = 0}^{7} {a}_{j} {α}^{j} + {\sum }_{j = 0}^{7} {a}_{j} {α}^{j} \\ = {\sum }_{j = 0}^{7} {a}_{j} {α}^{3 j} + {\sum }_{j = 0}^{6} {\sum }_{k = j + 1}^{7} {a}_{j} {a}_{k} ( {α}^{2 j + k} + {a}^{j + 2 k} )\end{matrix} \qquad ( 14 )$$

The system 600 may provide a first subset of the decoding values 610 to a coefficient generator (e.g., the coefficient generator 430) and/or an error position generator (e.g., the error position generator 435). The first subset may include the decoding value 610-a, the decoding value 610-b, and the decoding value 610-c. The coefficient generator may provide a first one or more coefficients associated with the decoding value 610-a and the decoding value 610-b to the error position generator. The error position generator may identify whether the i^{th} symbol of a codeword (e.g., the codeword 405) includes an error. Additionally, the system 600 may provide a second subset of the decoding values to the coefficient generator and/or an error value generator (e.g., the error value generator 465). The second subset may include the decoding value 610-b, the decoding value 610-d, and the decoding value 610-e. The coefficient generator may provide a second one or more coefficients to the error value generator. The error value generator may generate the error value for the i^{th} symbol of a codeword eᵢ.

For example, the errors of the codeword may be described in terms of an error locator polynomial Λ(x) that may indicate a position of the errors and an error equation polynomial Ω(x) that may indicate the value of the errors. The key equations of the error locator polynomial may be written in terms of unknown coefficients Λ₁ and Λ₂ of the error locator polynomial, as shown by equations 15 and 16.

$${S}_{3} {Λ}_{1} + {S}_{2} {Λ}_{2} = {S}_{4} \qquad ( 15 )$$

$${S}_{2} {Λ}_{1} + {S}_{1} {Λ}_{2} = {S}_{3} \qquad ( 16 )$$

If A≠0, then the rank of the key equations 15 and 16 is full, and the codeword includes two errors. In this case, Λ₁ and Λ₂ may be written in terms of the syndrome values 605 and A, as shown in equations 17 and 18.

$${Λ}_{1} = \frac{{S}_{2} {S}_{3} + {S}_{1} {S}_{4}}{A} \qquad ( 17 )$$

$${Λ}_{2} = \frac{{S}_{3}^{2} + {S}_{2} {S}_{4}}{A} \qquad ( 18 )$$

Further, the error equation polynomial Ω(x) may be written in terms of the syndrome values 605 and A, as shown in equation 19.

$$Ω ( x ) = {S}_{1} + \frac{{S}_{2}^{3} + {S}_{1}^{2} {S}_{4}}{A} x = {S}_{1} + ( {S}_{2} + {S}_{1} {Λ}_{1} ) x \qquad ( 19 )$$

Assuming that x=α⁻ⁱ, the error value eᵢ is thus given by equation 20.

$${e}_{i} = \frac{Ω ( x )}{{Λ}^{′} ( x )} = \frac{{S}_{1}}{{Λ}_{1}} + \frac{{S}_{2}}{{Λ}_{1}} x + {S}_{1} x \qquad ( 20 )$$

The error locator polynomial may thus be written in terms of A, B, and C, as shown by equation 21.

$$A Λ ( x ) = A + B x + C {x}^{2} \qquad ( 21 )$$

Similarly, the equation for the error value eᵢ may be written in terms of B, D, and E, as shown in equation 22.

$$B {e}_{i} = {S}_{1} A + ( {S}_{2} A + {S}_{1} B ) x = D + E x \qquad ( 22 )$$

Accordingly, if Λ(x)=0, then equations 23 and 24 are satisfied when there is an error in the i^{th} symbol of the codeword.

$$A {α}^{2 i} + B {α}^{i} + C = 0 \qquad ( 23 )$$

$${e}_{i} B + D + E {α}^{- 1} = 0 \qquad ( 24 )$$

Alternatively, if A=0, then the rank of the key equations 16 and 17 is not full, and the codeword includes a single error. In this case, Λ₂=0, and Λ₁ may be written in terms of the syndrome values 605, as shown in equation 25.

$${Λ}_{1} = \frac{{S}_{2}}{{S}_{1}} \qquad ( 25 )$$

Thus, the error locator polynomial may be written as shown in equation 26.

$${S}_{1} Λ ( x ) = {S}_{1} + {S}_{2} x \qquad ( 26 )$$

Accordingly, the error equation polynomial may be written as shown in equation 27.

$$Ω ( x ) = {S}_{1} \qquad ( 27 )$$

Further, the equation for the error value eᵢ may be written as shown in equation 28.

$${e}_{i} = \frac{{S}_{1}^{2}}{{S}_{2}} \qquad ( 28 )$$

Table 2 may summarize equations 6 through 28 in the case in which the codeword includes two errors (e.g. A≠0) and in the case in which the codeword includes one error (e.g., A=0).

TABLE 2

| Two errors | One error |
|---|---|
| $A = {S}_{1} {S}_{3} + {S}_{2}^{2} \neq 0$ | A = 0 |
| B = S₂S₃ + S₁S₄ | B = S₂ |
| $C = {S}_{3}^{2} + {S}_{2} {S}_{4}$ | C = S₃ |
| $D = {S}_{1}^{2} {S}_{3} + {S}_{1} {S}_{2}^{2}$ | $D = {S}_{1}^{2}$ |
| $E = {S}_{2}^{3} + {S}_{1}^{2} {S}_{4}$ | E = 0 |

Λ(x) = 1 + Λ₁x + Λ₂ x²
Λ′(x) = Λ₁
Ω(x) = S₁ + (S₂ + S₁Λ₁)

| | |
|---|---|
| ${Λ}_{1} = \frac{B}{A} {Λ}_{2} = \frac{C}{A}$ | ${Λ}_{1} = \frac{{S}_{2}}{{S}_{1}} = \frac{{S}_{3}}{{S}_{2}} {Λ}_{2} = 0$ |
| $Ω ( x ) = {S}_{1} + ( {S}_{2} + \frac{{S}_{1} B}{A} ) x$ | Ω(x) = S₁ |
| ${e}_{i} = \frac{Ω ( x )}{{Λ}^{′} ( x )} = \frac{{S}_{1} + ( {S}_{2} + {S}_{1} {Λ}_{1} ) x}{{Λ}_{1}}$ | ${e}_{i} = \frac{{S}_{1}}{{Λ}_{1}} = \frac{{S}_{1}^{2}}{{S}_{2}}$ |
| Λ = 0 ⇒ Aα²ⁱ + Bαⁱ + C = 0 | Λ = 0 ⇒ S₂αⁱ + S₃ = 0 |
| i ∈ 0, ... , 37 | i ∈ 0, ... , 37 |
| Beᵢ = D + E_{α}⁻ⁱ | ${S}_{2} {e}_{i} = {S}_{1}^{2}$ |

As indicated above, FIG. 6 is provided as an example. Other examples may differ from what is described with regard to FIG. 6.

FIG. 7 is a diagram illustrating an example of a system 700 that supports combinational error control components in stacked memory systems. The system 700 may include a coefficient generator 705, which may be a coefficient generator 430. For example, the system 700 may be implemented within a combinational error control component, such as the combinational error control component 240. The system 700 may be configured to obtain a decoding value and output one or more coefficients 710, such as a coefficient 710-a, a coefficient 710-b, through a coefficient 710-N based on linear combinations 715 of the decoding value.

As described herein, a linear combination 715 of a decoding value may be a single bit equal to the sum (e.g., the XOR) of each bit of the decoding value, where each bit is multiplied by the respective value (e.g., multiplied by one or zero). For example, the k^{th} linear combination 715 (LC^{k}) of the decoder value A, in which Aⱼ may be the j^{th} bit of the decoder value A, may be defined by a vector a^{k} having values

$${a}_{j}^{k}$$

equal to one or zero, as shown in equation 29. Each vector a^{k} may include a unique sequence of ones and zeros. By way of example, a⁰=[0,0,0,0,0,0,0,0], a¹=[0,0,0,0,0,0,0,1], a²=[0,0,0,0,0,0,1,0], and so on.

$$L {C}^{k} = {\sum }_{j = 0}^{7} {a}_{j}^{k} {A}_{j} \qquad ( 29 )$$

Each vector a^{k} may include a unique sequence of ones and zeros. By way of example, suppose that A=[1,1,0,1,0,1,1,1]. Further, suppose a⁰=[0,0,0,0,0,0,0,0], a¹=[0,0,0,0,0,0,0,1], a²=[0,0,0,0,0,0,1,0], and so on. In such an example, the linear combination LC¹ of A would be given by equation 30.

$$\begin{matrix}L {C}^{1} = {\sum }_{j = 0}^{7} {a}_{j}^{1} {A}_{j} \\ = 0 \cdot 1 + 0 \cdot 1 + 0 \cdot 0 + 0 \cdot 1 + 0 \cdot 0 + 0 \cdot 1 + 0 \cdot 1 + 1 \cdot 1 \\ = 0 + 0 + 0 + 0 + 0 + 0 + 0 + 1 \\ = 1\end{matrix} \qquad ( 30 )$$

Accordingly, if the decoder value A and the vector a^{k} are eight bit values, then there may be 256 possible linear combinations 715 of the decoder value (e.g., one linear combination for each possible vector a^{k}, where k ∈{0,1,2, . . . 255}).

A given bit 720 of a coefficient 710 may be equal to a particular linear combination 715 of the decoder value associated with the coefficient 710. Said another way, the j^{th} bit 720 of a coefficient may be equal to a particular linear combination LC^{k}. For example, a first bit 720 of the coefficient Aα²ⁱ (e.g., (Aα²ⁱ)₀) may be equal to a linear combination LC⁴, a second bit 720 of the coefficient Aα²ⁱ (e.g., (Aα²ⁱ)₁) may be equal to a linear combination LC¹², and so on. Although particular values for a^{k} are given, such values are merely illustrative. Other choices for a^{k} may be used to enable the techniques described herein.

A coefficient generator 705 may be configured such that each bit 720 of each coefficient 710 is selected from the linear combinations 715. For example, a first coefficient generator 705 configured to generate the coefficients Aα²ⁱ (e.g., the coefficient generator 430-a) may select each bit (Aα²ⁱ), for each i∈{0,1,2 . . . 37} and each j∈{0,1,2 . . . 7}. The first coefficient generator 705 may provide the coefficients Aα²ⁱ to the error position generator 435 (e.g., may provide the i^{th} coefficient Aα²ⁱ to the i^{th} combinational circuit 440). Similarly, a second coefficient generator 705 configured to generate the coefficients Bαⁱ (e.g., the coefficient generator 430-b) may select each bit (Bαⁱ), for each i∈{0,1,2 . . . 37} and each j∈{0,1,2 . . . 7}. The second coefficient generator 705 may provide the coefficients Bαⁱ to the error position generator 435. Additionally, a third coefficient generator 705 configured to generate the coefficients Eα⁻ⁱ (e.g., the coefficient generator 430-c) may select each bit (Eα⁻ⁱ)ⱼ for each i∈{0,1,2 . . . 37} and each j∈{0,1,2 . . . 7}. The third coefficient generator 705 may provide the coefficients Eα⁻ⁱ to the error value generator 465 (e.g., may provide the i^{th} coefficient Eα⁻ⁱ to the i^{th} combinational circuit 475).

As indicated above, FIG. 7 is provided as an example. Other examples may differ from what is described with regard to FIG. 7.

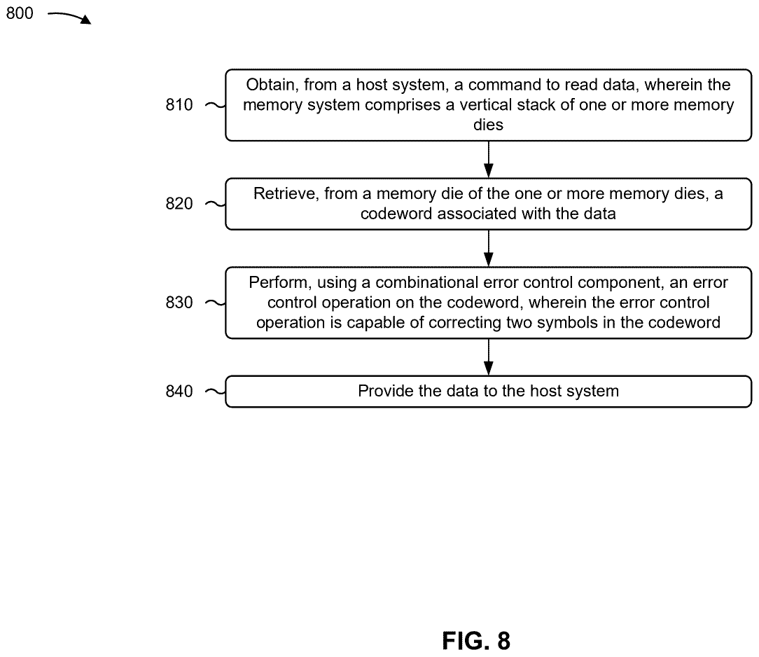

FIG. 8 is a flowchart of an example method 800 associated with combinational error control components in stacked memory systems. In some implementations, a memory system (e.g., the memory system 110) may perform or may be configured to perform the method 800. In some implementations, another device or a group of devices separate from or including the memory system (e.g., the host system 105 and/or the host interface 140) may perform or may be configured to perform the method 800. Additionally, or alternatively, one or more components of the memory system (e.g., the memory system controller 115, one or more memory devices 120, one or more local controllers 125, one or more memory arrays 130, one or more memory interfaces 145, a system 200, an encoder 300, a system 400, a system 500, a system 600, and/or a system 700) may perform or may be configured to perform the method 800. Thus, means for performing the method 800 may include the memory system and/or one or more components of the memory system. Additionally, or alternatively, a non-transitory computer-readable medium may store one or more instructions that, when executed by the memory system, cause the memory system to perform the method 800.

As shown in FIG. 8, the method 800 may include obtaining, from a host system, a command to read data, where the memory system comprises a vertical stack of one or more memory dies (block 810). As further shown in FIG. 8, the method 800 may include retrieving, from a memory die of the one or more memory dies, a codeword associated with the data (block 820). As further shown in FIG. 8, the method 800 may include performing, using a combinational error control component, a double symbol error control operation on the codeword (block 830). As further shown in FIG. 8, the method 800 may include providing the data to the host system (block 840).

The method 800 may include additional aspects, such as any single aspect or any combination of aspects described below and/or described in connection with one or more other methods or operations described elsewhere herein.

In a first aspect, performing the double symbol error control operation includes generating, using the combinational error control component and based on the codeword, a syndrome, generating, using the combinational error control component and based on the syndrome, one or more decoding values, and correcting, using the combinational error control component, one or more symbols in the codeword.

In a second aspect, alone or in combination with the first aspect, correcting the one or more symbols includes obtaining, at an error value generator, a subset of the one or more decoding values, generating an error value using the subset of the one or more decoding values, and combining the error value with the codeword to correct the one or more symbols.

In a third aspect, alone or in combination with one or more of the first and second aspects, the method 800 includes obtaining, from the host system, a second command to store the data, generating, at an encoder of the combinational error control component, parity information, where the codeword includes the parity information and the data, and storing the codeword to the memory die.

In a fourth aspect, alone or in combination with one or more of the first through third aspects, the one or more memory dies includes the combinational error control component

In a fifth aspect, alone or in combination with one or more of the first through fourth aspects, the memory system further includes a buffer die, the buffer die including the combinational error control component.

In a sixth aspect, alone or in combination with one or more of the first through fifth aspects, the codeword includes a payload, metadata associated with the payload, and parity information, and the combinational error control component is configured to perform the double symbol error control operation using the parity information.

Although FIG. 8 shows example blocks of a method 800, in some implementations, the method 800 may include additional blocks, fewer blocks, different blocks, or differently arranged blocks than those depicted in FIG. 8. Additionally, or alternatively, two or more of the blocks of the method 800 may be performed in parallel. The method 800 is an example of one method that may be performed by one or more devices described herein. These one or more devices may perform or may be configured to perform one or more other methods based on operations described herein.

In some implementations, a method includes obtaining, by a memory system and from a host system, a command to read data, where the memory system comprises a vertical stack of one or more memory dies; retrieving, by the memory system and from a memory die of the one or more memory dies, a codeword associated with the data; performing, by the memory system and using a combinational error control component, a double symbol error control operation on the codeword; and providing the data to the host system.

In some implementations, a memory device includes a vertical stack of one or more memory dies; one or more channels configured to couple respective subsets of the one or more memory dies to a buffer die; and one or more combinational error control components, where a combinational error control component of the one or more combinational error control components is configured to perform a double symbol error control operation on a codeword associated with a memory die of the one or more memory dies.

In some implementations, a memory apparatus includes a vertical stack of one or more memory dies; a buffer die comprising one or more combinational error control components, where a combinational error control component of the one or more combinational error control components is configured to perform a double symbol error control operation on a codeword associated with a memory die of the one or more memory dies; and one or more channels coupling respective subsets of the one or more memory dies to the buffer die.

In some implementations, a memory apparatus includes a vertical stack of one or more memory dies, the one or more memory dies comprising respective sets of combinational error control components, where a combinational error control component of the respective sets of combinational error control components is configured to perform a double symbol error control operation on a codeword associated with a memory die of the one or more memory dies; and one or more channels configured to couple respective subsets of the one or more memory dies to a buffer die.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method, comprising:
obtaining, by a memory system and from a host system, a command to read data, wherein the memory system comprises a vertical stack of one or more memory dies;
retrieving, by the memory system and from a memory die of the one or more memory dies, a codeword associated with the data;
performing, by the memory system and using a combinational error control component, a double symbol error control operation on the codeword; and
providing the data to the host system.

2. The method of claim 1, wherein performing the double symbol error control operation comprises:
generating, using the combinational error control component and based on the codeword, a syndrome;
generating, using the combinational error control component and based on the syndrome, one or more decoding values; and
correcting, using the combinational error control component, one or more symbols in the codeword.

3. The method of claim 2, wherein correcting the one or more symbols comprises:
obtaining, at an error value generator, a subset of the one or more decoding values;
generating an error value using the subset of the one or more decoding values; and
combining the error value with the codeword to correct the one or more symbols.

4. The method of claim 1, further comprising:
obtaining, from the host system, a second command to store the data;
generating, at an encoder of the combinational error control component, parity information, wherein the codeword includes the parity information and the data; and
storing the codeword to the memory die.

5. The method of claim 1, wherein the one or more memory dies includes the combinational error control component.

6. The method of claim 1, wherein the memory system further includes a buffer die, the buffer die comprising the combinational error control component.

7. The method of claim 1, wherein the codeword comprises a payload, metadata associated with the payload, and parity information, and wherein the combinational error control component is configured to perform the double symbol error control operation using the parity information.

8. A memory device, comprising:
a vertical stack of one or more memory dies;
one or more channels configured to couple respective subsets of the one or more memory dies to a buffer die; and
one or more combinational error control components, wherein a combinational error control component of the one or more combinational error control components is configured to perform a double symbol error control operation on a codeword associated with a memory die of the one or more memory dies.

9. The memory device of claim 8, wherein the one or more memory dies include respective subsets of the one or more combinational error control components.

10. The memory device of claim 8, wherein the buffer die includes the one or more combinational error control components.

11. The memory device of claim 8, wherein the codeword comprises a payload, metadata associated with the payload, and parity information, and wherein the combinational error control component is configured to perform the double symbol error control operation using the parity information.

12. The memory device of claim 8, wherein the combinational error control component comprises:
a syndrome generator configured to generate a syndrome based on the codeword;
a decoding value generator coupled to the syndrome generator, the decoding value generator configured to generate one or more decoding values based on the syndrome and using one or more first combinational circuits;
an error value generator configured to generate an error value associated with the codeword based on the one or more decoding values; and
an error position generator coupled to the decoding value generator, the error position generator configured to obtain a subset of the one or more decoding values and generate, using one or more second combinational circuits, one or more values indicating a position of the error value.

13. The memory device of claim 12, wherein the one or more combinational circuits are configured to obtain respective subsets of one or more syndrome values of the syndrome and configured to output respective decoding values of the one or more decoding values.

14. The memory device of claim 12, wherein the combinational error control component further comprises:
one or more coefficient generators coupled to the decoding value generator, the one or more coefficient generators configured to obtain respective decoding values of the one or more decoding values and provide respective sets of coefficients of the respective decoding values to the error position generator.

15. The memory device of claim 12, wherein the combinational error control component further comprises:
an encoder configured to generate the codeword using one or more third combinational circuits and data associated with a write command, wherein the codeword includes the data.

16. A memory apparatus, comprising:
a vertical stack of one or more memory dies;
a buffer die comprising one or more combinational error control components, wherein a combinational error control component of the one or more combinational error control components is configured to perform a double symbol error control operation on a codeword associated with a memory die of the one or more memory dies; and
one or more channels coupling respective subsets of the one or more memory dies to the buffer die.

17. The memory apparatus of claim 16, wherein the codeword comprises a payload, metadata associated with the payload, and parity information, and wherein the combinational error control component is configured to perform the double symbol error control operation using the parity information.

18. The memory apparatus of claim 16, wherein the combinational error control component comprises:
a syndrome generator configured to generate a syndrome based on the codeword;
a decoding value generator coupled to the syndrome generator, the decoding value generator configured to generate one or more decoding values based on the syndrome and using one or more combinational circuits;
an error value generator configured to generate an error value associated with the codeword based on the one or more decoding values; and
an error position generator coupled to the decoding value generator, the error position generator configured to obtain a subset of the one or more decoding values and generate, using one or more second combinational circuits, one or more values indicating a position of the error value.

19. The memory apparatus of claim 18, wherein the one or more combinational circuits are configured to obtain respective subsets of one or more syndrome values of the syndrome and configured to output respective decoding values of the one or more decoding values.

20. The memory apparatus of claim 18, wherein the combinational error control component further comprises:
one or more coefficient generators coupled to the decoding value generator, the one or more coefficient generators configured to obtain respective decoding values of the one or more decoding values and provide respective sets of coefficients of the respective decoding values to the error position generator.

21. A memory apparatus, comprising:
a vertical stack of one or more memory dies, the one or more memory dies comprising respective sets of combinational error control components, wherein a combinational error control component of the respective sets of combinational error control components is configured to perform a double symbol error control operation on a codeword associated with a memory die of the one or more memory dies; and
one or more channels configured to couple respective subsets of the one or more memory dies to a buffer die.

22. The memory apparatus of claim 21, wherein the codeword comprises a payload, metadata associated with the payload, and parity information, and wherein the combinational error control component is configured to perform the double symbol error control operation using the parity information.

23. The memory apparatus of claim 21, wherein the combinational error control component comprises:
a syndrome generator configured to generate a syndrome based on the codeword;
a decoding value generator coupled to the syndrome generator, the decoding value generator configured to generate one or more decoding values based on the syndrome and using one or more combinational circuits;
an error value generator configured to generate an error value associated with the codeword based on the one or more decoding values; and
an error position generator coupled to the decoding value generator, the error position generator configured to obtain a subset of the one or more decoding values and generate, using one or more second combinational circuits, one or more values indicating a position of the error value.

24. The memory apparatus of claim 23, wherein the one or more combinational circuits are configured to obtain respective subsets of one or more syndrome values of the syndrome and configured to output respective decoding values of the one or more decoding values.

25. The memory apparatus of claim 23, wherein the combinational error control component further comprises:
one or more coefficient generators coupled to the decoding value generator, the one or more coefficient generators configured to obtain respective decoding values of the one or more decoding values and provide respective sets of coefficients of the respective decoding values to the error position generator.
